(19) United States
(12) Patent Application Publication
(10) Pub. No.: US 2007/0036007 A1
(43) Pub. Date: Feb. 15, 2007

(54) Sticky bit buffer

(75) Inventors: Ameet Lann, Macabim (IL); Kobi Danon, Rishon Lezion (IL); Mori Edan, Carmel (IL); Shay Galanti, Kfar Saba (IL)

Correspondence Address: TIAJOLOFF & KELLY, CHRYSLER BUILDING, 37TH FL, 405 LEXINGTON AVE, NEW YORK, NY, 10174, US

(73) Assignee: Saifun Semiconductors, Ltd., Netanya (IL)

(21) Appl. No.: 11/200,387

(22) Filed: Aug. 9, 2005

(51) Int. Cl. G11C 5/14

(52) U.S. Cl. 365/189.09

(57) ABSTRACT

A method for programming in parallel reference cells to be used for operating other cells of a memory cell array, the method including: a) reading each of the reference cells of a memory cell array with a sense amplifier, the sense amplifier providing an output indicative of a programmed state of the reference cell relative to another bit in the array, b) reading each of the reference cells of a memory cell array with a sense amplifier while using read conditions to determine if the reference cells have reached a target level, c) determining if a programming pulse should be applied to the reference cell by comparing the output of the sense amplifier to a predefined target “0” or “1”, d) setting a buffer bit, corresponding to the output of the sense amplifier, in a sticky bit buffer to a first logical state if the reference cell needs to be programmed, and not changing a logical state of the buffer bit if the reference cell does not need to be programmed, e) performing steps a)-d) for a desired address range in the array, f) performing steps a)-d) for a desired number of reference cells, g) setting a sticky bit of the sticky bit buffer to a first logical state if one of the buffer bits indicates that one of the reference cells must be programmed, and if none of the buffer bits indicates that one of the reference cells must be programmed, then not changing a logical state of the sticky bit, h) reading the sticky bit, and i) applying a program pulse to the reference cell whose corresponding sticky bit is set to the first logical state.

### FIELD OF THE INVENTION

The present invention relates to sensing schemes for read operations on semiconductor devices, such as memory cells of non-volatile memory (NVM) arrays, and, more particularly, to a method for programming a reference cell for use in a read operation.

### BACKGROUND OF THE INVENTION

Memory devices, such as random access memory (RAM), read-only memory (ROM), non-volatile memory (NVM) and the like, store data in memory cells. An output electrical signal may provide an indication of the data that is stored in the cells. A sense amplifier is widely used to detect the output signal for determining the logical content thereof.

In general, prior art sense amplifiers determine the logical value stored in the cell by comparing the output of the cell with a threshold voltage level. If the output is above the threshold the cell is considered erased (with a logical value of 1), and if the output is below the threshold the cell is considered programmed (with a logical value of 0).

Typically, a sufficient difference is defined between the expected erased and programmed voltage levels so that noise on the output will not cause false results. The threshold level is typically set as a voltage level between the expected erased and programmed voltage levels, with a sufficient margin above and below the threshold level. For example, the expected erased and programmed voltage levels may be 2.5V and 1.5V, respectively, and the threshold level may be set as 2V.

The margin may help maintain the same reading for the programmed or erased state of the cell. The margin may be necessary to overcome imperfections in the reading process and to compensate for drifts in the cell's threshold voltage (e.g., caused by retention loss or program/erase disturbs). A reduction in the original margin due to imperfections in the reading process (e.g., due to operation at different operational conditions) is referred to as “margin loss.”

In the prior art, predetermined fixed values for the threshold voltage of each of the reference cells may be selected by the memory device manufacturer/designer prior to manufacturing the memory devices. In selecting these fixed threshold voltage values, one of the variables that should be taken into account is the amount of variation that occurs in the initial threshold voltage of the memory array cells during manufacturing of the memory devices. Another variable is the amount of time required to adjust the threshold voltage of the memory array cells during set up of the memory device so that all the cells have a threshold voltage below the predetermined fixed value of threshold voltage for the reference cell. In some memory devices, however, the time required to adjust the threshold voltage of the memory array cells can be especially time consuming. Furthermore, some types of memory devices have a limited capacity to adjust the threshold voltage of the memory array cells.

One prior art attempt to solve these problems is described in U.S. Pat. No. 6,449,190 to Bill. A memory device setup procedure is provided for adapting reference cells to the memory array cells. In one stage of the method, an erase verify reference cell is adapted to the memory array cells until substantially all of the memory array cells have threshold voltages less than the threshold voltage of the erase verify reference cell. In another stage of the method, a program verify reference cell is setup by increasing the threshold voltage of the program verify reference cell by a desired change in voltage above the threshold voltage of the erase verify reference cell. A read reference cell is setup by changing the threshold voltage of the read reference cell so that it is intermediate between the erase verify reference cell and the program verify reference cell. Comparing circuits are also provided for changing the threshold voltages of the reference cells to the desired levels.

However, this method does not provide a practical way of accessing the sense amplifiers and reference cells in parallel.

Another solution to this problem is disclosed in U.S. Pat. No. 6,128,226 to Eitan and Dadashev, and is applicable for sensing a close-to-ground signal received from the memory cell. The method uses a reference cell to generate a reference signal instead of using a fixed reference voltage value. More specifically, the method employs a reference unit with a reference cell and a timing unit with a timing cell, having a similar structure and a similar current path therethrough to that of the memory cell Initially, the memory cell array, the reference unit and the timing unit are discharged, thereby generating a cell signal, a reference signal and a timing signal, respectively. Upon charging, a read signal is generated when the timing signal at least reaches a predefined voltage level. Once the read signal is generated, a sensing signal is generated from the difference of the cell and reference signals The reference unit has a reference capacitance which is a multiple of the expected capacitance of a bit line of the array and the timing unit has a predefined timing capacitance.

U.S. Pat. No. 6,134,156 to Eitan, assigned to the same assignee of the present invention, describes another method for sensing a close-to-ground signal received from the memory cell. The method includes the steps of charging a drain of the selected memory cell to a ground potential, charging a source of the selected memory cell to a predetermined voltage potential, detecting the voltage level on the drain and comparing the detected voltage level with a reference voltage level, thereby producing a comparison result Here again, a reference cell is used to generate a reference signal in lieu of a fixed reference voltage value.

One of the advantages of using a reference cell instead of a fixed threshold for comparison is that a low voltage signal may be reliably processed irrespective of any changes in temperature or power supply level.

When close to ground signals are sensed as in the aforementioned U.S. Pat. Nos. 6,134,156 and 6,128,226 patents, the reference cell signal develops at an intermediate rate between that of a programmed cell and an erased cell. When set this way, the array cells' signals on one side of the reference signal are determined to be programmed cells, while signals on the other side of the reference signal are determined to be erased cells. For example, array cells generating signals smaller than the reference signal are considered programmed and array cells generating signals larger than the reference signal are considered erased. Such placement may be achieved by using a reference cell whose current is between the erased and programmed cells' current levels. The reference cell's current level may be controlled by the reference cell's size, its programming level, or its gate voltage level. Furthermore, if voltage signals are used to detect the cells' contents, then the reference signal placement may be controlled by providing a different load capacitance on the reference cell compared to that of the array cells. However, if the array and the reference cells differ in their sizes, in their operating gate voltages, or in their loads then some margin loss will be introduced to the sensing scheme. On the other hand, placing the reference cells' signals by properly programming the reference cells (while operating the array and reference cells at identical conditions) minimizes the sensing scheme sensitivity to operating conditions, process parameters and environmental conditions variations, thereby minimizing the margin loss, if any, that is introduced to the sensing system.

Accordingly, there are difficulties attendant with reliable programming of a reference cell so as to minimize operating margin loss, as well as accurate placement of a programmed reference cell relative to the memory array cells.

U.S. Pat. No. 6,584,017, assigned to the same assignee of the present invention, describes another method, aimed at solving the abovementioned problems. This method may be used to minimize margin loss and maximize cycling performance in programming reference cells. The method may be used to program one or more reference cells relative to a prescribed cell on the same die as the reference cell (e.g., a memory cell or a golden bit cell).

The method of that patent application first finds the threshold voltage for the memory cell in the memory array that has the highest native threshold voltage value (VTNH). Then it sets the golden bit gate voltage at a level where its threshold voltage relative to a reference cell will be the target of the reference cell programming. The reference cell is programmed a predetermined amount and its program state is sensed relative to the golden bit memory cell. The programming and sensing steps are repeated until the sensing step indicates that the reference cell has been programmed an amount sufficient to fail (or pass) a first preselected read operation.

The method of that patent application may be suitable for memory devices with a relatively small number of sense amplifiers and reference cells. However, as the number of sense amplifiers increase, the number of reference cells increases, and the amount of time spent on finding VTNH for each sense amplifier increases dramatically.

One problem in many products is that all the array (at least in a range greater than the bits of the relevant ref cell itself), must be read many times for each reference cell. It is very complicated externally to read and store all the bits for each reference cell (although some types of testers can handle it with proper configuration). Second, since the cell with the VTNH is unknown, the entire array must be read again after each pulse to check if another program pulse must be applied. Third, since each reference cell may need another target, as it is slightly different from the other reference cells (having different initial currents, different sense amplifiers and work vs. different cells in the array), the entire array must be read for each reference cell

### SUMMARY OF THE INVENTION

The present invention seeks to provide a method for programming a reference cell or any number of reference cells in parallel. In accordance with an embodiment of the invention, part of the reference cells may be programmed relative to some selected initial reference voltage (not necessarily the highest initial VTNH), and subsequently other reference cells may be programmed relative to a prescribed cell on the same die as the reference cell (e.g., a memory cell or a golden bit cell).

According to one embodiment of the invention, the method comprises reading portions of the array, portion after portion, while programming the reference cells. Each step is a loop that consists of two operations:

(i) reading the specific portion of the array using a pre-selected read operation. A sticky bit buffer may be used in this read operation, as is described more in detail hereinbelow.

(ii) programming all the reference cells that need to be programmed, as indicated by the sticky bit buffer, by a predetermined programming pulse.

The loop continues until all the reference cells in that portion of the array that need to be programmed are indeed programmed. The same loop may then be repeated on the other portions of the array, until the entire array is read. The outcome of the above process is a reference cell (or reference cells) that may be programmed to a predetermined amount, wherein the program state is sensed relative to the VTNH memory cell For example, if there is just one reference cell per sense amplifier (e.g., the read reference cell) the process of reference programming for that specific sense amplifier (and all other sense amplifiers that were programmed in parallel to it), is finished.

It is noted that in this embodiment of the invention there is no need to initially find the highest VTNH and then afterwards program the reference cells relative to it, as in the prior art. Rather the process performs reference programming and finds the VTNH memory cell in parallel (the programming and VTNH are “intermixed”).

According to another embodiment of the invention, a method for programming a set of reference cells for use in performing respective read operations on an integrated circuit memory having a plurality of memory cells is described, The programming of the first reference cell (e.g., a reference voltage read signal or any other reference cell) may be carried out as just described above. Then, as described in U.S. Pat. No. 6,584,017, other reference voltage signals may be placed relative to the previous reference voltage signals using the golden bit cell. For example, a reference voltage erase verify signal may be placed relative to the reference voltage read signal, and a reference voltage program verify signal may be placed relative to the reference voltage read signal and/or the reference voltage erase verify signal.

The foregoing methods may have their sensing steps performed relative to the VTNH memory cell, or alternatively, relative to a native cell (a golden bit cell) on-board the same die.

The inventive method may be utilized to program a reference cell used with a memory array, a sliced array having one or more columns of memory cells, and redundant or auxiliary arrays.

There is thus provided in accordance with an embodiment of the invention a method for programming in parallel reference cells to be used for operating other cells of a memory cell array, the method including: a) reading each of the reference cells of a memory cell array with a sense amplifier, the sense amplifier providing an output indicative of a programmed state of the reference cell relative to another bit in the array,

b) reading each of the reference cells of a memory cell array with a sense amplifier while using read conditions to determine if the reference cells have reached a target level,

c) determining if a programming pulse should be applied to the reference cell by comparing the output of the sense amplifier to a predefined target “0” or “1”,

d) setting a buffer bit, corresponding to the output of the sense amplifier, in a sticky bit buffer to a first logical state if the reference cell needs to be programmed, and not changing a logical state of the buffer bit if the reference cell does not need to be programmed,

e) performing steps a)-d) for a desired address range in the array,

f) performing steps a)-d) for a desired number of reference cells,

g) setting a sticky bit of the sticky bit buffer to a first logical state if one of the buffer bits indicates that one of the reference cells must be programmed, and if none of the buffer bits indicates that one of the reference cells must be programmed, then not changing a logical state of the sticky bit,

h) reading the sticky bit, and

i) applying a program pulse to the reference cell whose corresponding sticky bit is set to the first logical state.

One or more program pulses may be applied to the reference cell until the reference cell is considered programmed relative to a predefined programmed level. A plurality of the reference cells of the memory cell array may be read in parallel.

In accordance with an embodiment of the invention the method further includes performing a logical operation on the buffer bits in order to determine if one of the reference cells must be programmed, the logical operation including a logical ‘OR’ of the buffer bits.

In accordance with another embodiment of the invention the method further includes repeating steps a)-h) until a plurality of the reference cells of the memory cell array are programmed relative to a predefined programmed level.

The sticky bit buffer may include a random access memory. The sticky bit buffer may include one sticky bit per sense amplifier or per more than one sense amplifier. The reference cells may include at least one of a reference cell for read, erase verify, program verify, PBEV (Program Before Erase Verify), PAEV (Program After Erase Verify), and other intermediate levels between the above Rd and verify levels.

In accordance with an embodiment of the invention the readout of the redundancy area is done through sense amplifier/s using the same sticky bit buffer but may require special handling.

Further in accordance with an embodiment of the invention steps a)-h) may be performed on a portion of the memory cell array defined as 1/N of the memory cell array. After performing steps a)-h) on the 1/N portion of the memory cell array, steps a)-h) may be performed on another portion of the memory cell array defined as 1/M of the memory cell array, perhaps with different programming conditions (N may be different from M).

In accordance with an embodiment of the invention the selected reference level includes an OTPG (one-time-programmable golden) reference bit on the memory cell area, wherein the OTPG bit is not programmed or erased during application of the method or during any future operation on the die. A voltage level of the OTPG bit may be used to program another reference cell of the memory cell array. The array may include a plurality of OTPG bits. The method may further include use of OTPGˆ bits wherein the OTPGˆ bit is not erased during application of the method, and include a phase of programming all the OTPGˆ bits to the same Vt level.

Note that the above distinguishes between OTPG and OTPGˆ: Without limitation to the scope of the invention, OTPG can be used as a reference for the shift of the reference cells after bake, and OTPGˆ can be used to speed up the flow and can get program pulses.

In accordance with an embodiment of the invention, the method further includes employing a real sticky operation to read the entire memory cell array, obtaining sticky bit buffer data, and updating another buffer called a program data buffer wherein the new program data buffer data=(sticky bit buffer data) OR (current program data buffer data), and wherein the content of the program data buffer is used to program the reference cells.

### BRIEF DESCRIPTION OF THE DRAWINGS

The present invention will be understood and appreciated more fully from the following detailed description taken in conjunction with the appended drawings in which:

FIG. 1 illustrates a spread of native threshold voltage values for a number of memory cells on a die (where the threshold voltage is determined by the result of the read versus the reference cell, and not by some predefined threshold current value);

FIG. 2 illustrates target threshold voltage values for programming reference cells in order to achieve exemplary and desired operating margins;

FIG. 2A illustrates a practical example of operating margins and a preferred sequence of steps to establish the operating margins relative to a particular cell within the memory array (but a different order of steps is also possible);

FIG. 3A illustrates a plot of signal development (integration of their current) of the VTNH cell and a reference cell when both are driven by the same VCCR_REF voltage supply (where VCCR_REF is the internal gate voltage that is used, for the ref cells and the memory cells, during the regular read operations);

FIG. 3B is the plot of FIG. 3A, showing the ref cell as before with Vgate=VCCR_REF, while the gate of the VTNH cell is being driven by a trimmed external supply voltage, wherein the external voltage presented is smaller than the internal Vgate by M (an internal trimmed voltage may be used instead of the external one);

FIG. 3C is the plot of FIG. 3B, showing the reference cell at various program states and the results of the read operations;

FIG. 3D illustrates a plot of signal development in the sense amplifier used in conjunction with the Rd_reference cell and erased and programmed cells in the array due to the normal user operation of erase and program, where OTP (one time programming), CR (column redundancy) and RR (row redundancy) are array cells located at different areas in the array);

FIG. 4 is a very simplified block diagram of a memory cell array comprising sense amplifiers and reference cells, for which methods of the present invention are described hereinbelow;

FIGS. 5A-5B are simplified block diagrams of a sticky bit buffer, useful with methods of the present invention for programming reference cells, in respective initial and non-initial states;

FIGS. 6A and 6B together form a simplified flow chart of a method for programming reference cells of a memory cell array, in accordance with an embodiment of the present invention;

FIG. 7 is a simplified flow chart of a method for programming reference cells of a memory cell array, in accordance with another embodiment of the present invention, wherein reference programming and finding the VTNH memory cell are intermixed in parallel;

FIGS. 8A and 8B together form a simplified flow chart of a method for programming reference cells of a memory cell array, in accordance with yet another embodiment of the present invention, wherein a first (already programmed) reference cell of a mini-array that contains all the reference cells used for the different read operation (e.g., Read, Erase Verify, Program Verify and the like) is used in the programming flow of the other reference cells in the mini array, by reading it using the shared sense amplifier relative to a reference bit referred to as an OTPG (one-time-programmable golden) bit. And;

FIG. 9 is a simplified flow chart of a method for even faster programming of the reference cells, in accordance with an embodiment of the present invention, wherein all of the OTPGˆ bits may be programmed to the same Vt level (wherein the OTPGˆ are the same as the OTPG bits except the fact that they are programmed and not left in their native state).

### DETAILED DESCRIPTION OF THE PRESENT INVENTION

By way of overview and introduction, the present invention is described in connection with a methodology for programming a reference cell to enable sensing of the contents of a memory cell from close to ground level. Such a memory array is described in U.S. Pat. Nos. 6,134,156 and 6,535,434. By using a reference cell instead of a fixed threshold for comparison, a low voltage signal may be reliably processed irrespective of any changes in temperature or power supply level. The present invention has applicability to other sensing schemes, including AC and DC sensing techniques, and with read operations from either the source or drain side of a transistor, as may be appreciated by those of skill in the art. The present invention may be applicable to other types of sensing which are not necessarily close to ground.

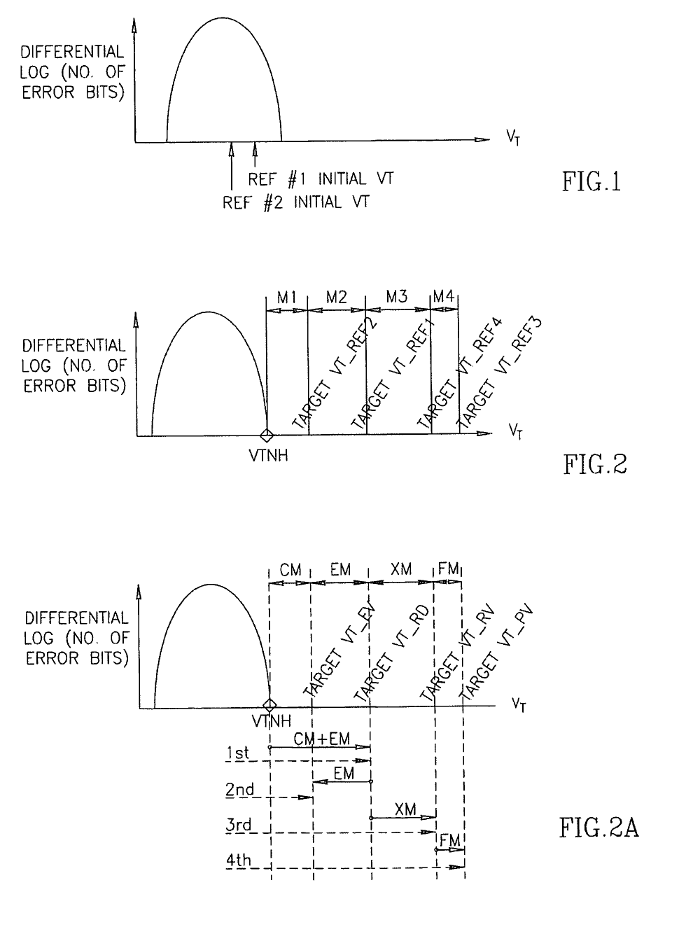

Reference is now made to FIG. 1, which illustrates the memory array cells' native threshold voltage distribution.

The memory cells on the die include both array cells that are addressed in a conventional manner, and additional cells, such as auxiliary and reference cells, which are used for a variety of purposes including quality control during manufacturing and read operations when the array cells are put into service. The native reference cells may lie anywhere along the threshold voltage (VT) axis. By way of example, the native threshold values for two reference cells are indicated as lying within the distribution curve, though that is not required.

The methods of the present invention enable precision programming of reference cells relative to a memory cell on the die, for example, relative to an array cell, another reference cell, or to a golden bit. Each of these techniques defines a related but different method described herein with reference to a flow diagram of a preferred embodiment for each such technique. These techniques are performed after manufacturing the devices, prior to placing the memory array into service. Generally, there are a number of target threshold voltage values that are set in a corresponding number of reference cells as a result of the reference cell programming process of the invention. That is to say, different types of read operations may be performed on the memory cell, such as program verify, erase verify and operations in which temporary states of a cell in the progress of an erase or a program operation should be detected. The basic difference presented by these in-progress read cycles is the placement of the reference cell threshold voltage. Since the reference cell's state is not changed according to the type of the read operation, different reference cells are preferably used for each of these types of operations.

Reference is now made to FIG. 2, which illustrates that target threshold voltage values may be spaced relative to one another by predetermined margins M1, M2, M3 and M4 which are established to ensure reliable reads, read verifies, erase verifies, program verifies, or other read operations on the array memory cells. To minimize and overcome margin loss and maximize product endurance and reliability, the margins M1, M2, M3 and M4 may provide a reliable buffer and supply the operating window. Additionally, the placement of the programmed reference cells may be defined (at least for one of the reference cells) relative to the array threshold voltage (VT) distribution.

FIG. 2 illustrates an example of the margins M1, M2, M3 and M4 established and positioned relative to the memory cell in the array having the highest native threshold value (“VTNH”). As will be appreciated from the discussion below, the margins may be established and positioned relative to any cell, such as the VTNH cell, a golden bit cell, or another reference cell. Although the margins in FIGS. 2 and 2A (are positive, negative margins can be accordingly used.

Reference is now made to FIG. 2A, which illustrates a practical example of the margins M1, M2, M3 and M4 that may be well defined using the techniques of the present invention. Four margins are illustrated: cycling margin (“CM”), erase margin (“EM”), retention margin (“XM”) and refresh margin (“FM”) These margins are maintained between the reference cells, once their threshold voltage values have been created using the reference programming flow described below. In other words, the margins are controlled based on the response of each reference cell when driving its gate by a standard voltage source VCCR. Since the reference programming procedure results in reference threshold voltages that may not be exactly as the original target levels, the actual reference cells threshold voltages may maintain the following margins:
VT_{—}RD_{—}REF_actual−VTNH≧CM+EM
VT_{—}RD_{—}REF_actual−VT_{—}EV_{—}REF_actual≧EM
VT_{—}RV_{—}REF_actual−VT_{—}RD_{—}REF_actual≧XM
VT_{—}PV_{—}REF_actual−VT_{—}RV_{—}REF_actual≧FM

where VT_RD_REF_actual is the threshold voltage value of a reference cell programmed to implement a cell-contents read operation,

VT_EV_REF_actual is the threshold voltage value of a reference cell programmed to implement an erase verify operation concerning the contents of a cell,

VT_RV_REF_actual is the threshold voltage value of a reference cell programmed to implement a refresh verify operation concerning the contents of a cell, and

VT_PV_REF_actual is the threshold voltage value of a reference cell programmed to implement a program verify operation concerning the contents of a cell.

Alternatively, instead of ≧ in the above equations, the present invention is also applicable for ≦, depending on the flow. For example, if the procedure starts with programming the read reference cell and then afterwards the erase verify reference cell, some over-programming may occur during the erase verify reference programming which may result in a smaller erase margin than planned. The actual erase margin (or any other margin) may be measured at the end of the flow, and a decision may be made, using a predetermined criterion, whether to mark the unit as “bad” for having insufficient or excessive margin. In principle, any reference cell may be under-programmed due to the inaccuracy of the sensing operation. Hence a reference cell may be read as “pass” although in a future reading, it may be read as “fail”.

FIG. 2A also illustrates a sequence of steps to establish the operating margins relative to a particular cell within the memory array. The steps in FIG. 2A are shown relative to the VTNH cell, though other cells may be used, such as a golden bit cell, as described below Use of the VTNH cell facilitates discussion because it clearly illustrates the relationship between the required threshold voltages to be programmed into the reference cells and the required operating margins. Thus, with reference to the VTNH cell, the RD_reference cell is programmed to the RD_Reference level, by programming it to have a margin M of CM+EM above VTNH. If a golden bit cell were used as the base line threshold voltage, then the margin M would most likely be greater by the difference between the threshold voltage of the golden bit cell (Votpg) and the VTNH cell.

Next, another reference cell is programmed to be the erase verify cell by programming that cell to have a margin EM below the actual threshold voltage of the RD_Reference cell, as may be appreciated from FIG. 2A. Likewise, the RV_Reference cell may be programmed to be XM above the actual threshold voltage of the RD_Reference cell, and another cell is programmed to be the PV_Reference cell by programming it to have a margin FM above the actual threshold voltage of the RV_REF. It will be appreciated that other arrangements of the reference cells' threshold voltages and of the sequence of programming the reference cells are possible and are part of the present invention. Furthermore, the placement of each reference cell may be made relative to an array cell, a “golden” cell, or another reference cell.

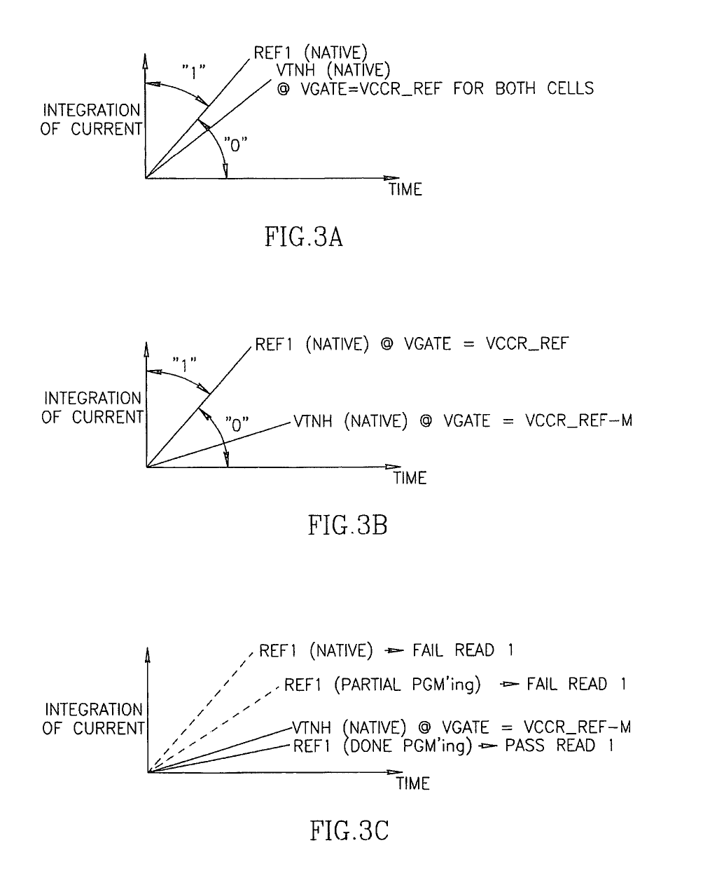

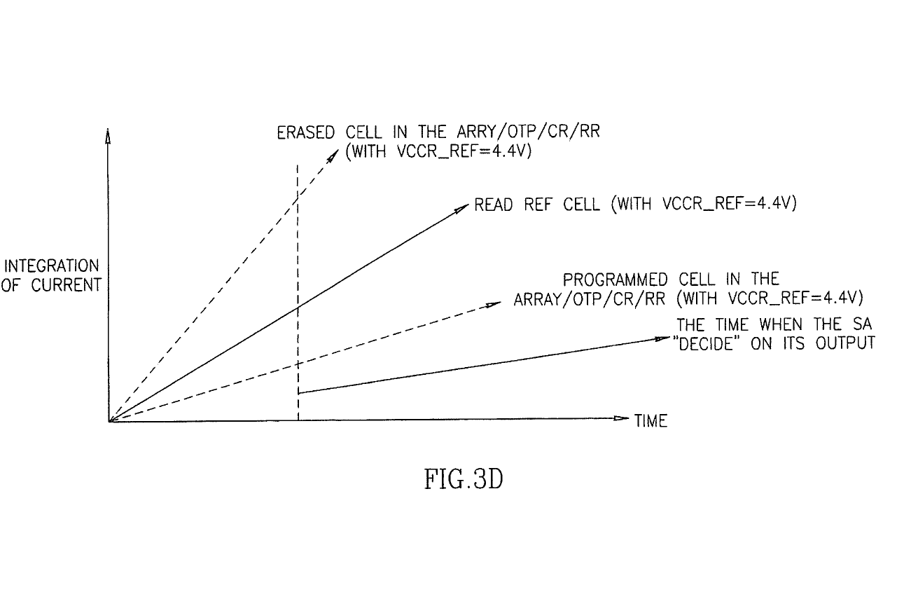

When put into service, it is desirable to drive both the array cells' and the reference cells' gates with the same voltage supply VCCR_REF during all standard read operations However, during reference programming, different voltages may be applied to the gate of the array cells (called VCCR) and the reference cells (VCCR_REF) The different voltage on the array cells may be a result of an internal trimming or a trimmable external voltage supply (EXT_VCCR) driving the array cells' gates. This difference in gate voltage is used to facilitate the reference cell programming procedure. The effect of trimming the internal/external VCCR supply is illustrated in FIGS. 3A, 3B, 3C and 3D. In FIG. 3A, the development over time of signals (integration of current), in the corresponding sense amplifier, from a given, native reference cell is plotted together with the VTNH cell when both are driven by the same gate voltage meaning VCCR=VCCR_REF A “pass read ‘1’” operation is defined to be when the array cell has a greater signal than the reference cell and a “fail read ‘1’” operation to be when the array cell signal is lower than the reference signal. For example, the result of a read operation between the native VTNH cell and the native reference cell shown in FIG. 3A will be “fail read ‘1’”. If the reference cell is programmed under these conditions until VTNH passes the read ‘1’ operation, the reference cell may normally have a margin ≧0 above the VTNH. However, it is in the scope of the invention to have any margin, that is, less than, equal to or greater than zero. To achieve such a predefined margin of any value, it is possible to have VCCR≠VCCR_REF as shown in FIG. 3B.

In FIG. 3B, the gate voltage (VCCR) applied to the VTNH cell has been reduced by a margin M, and the lower gate voltage results in slower signal development of that cell in the SA Consequently, when VTNH is driven at the lower trimmed supply voltage level, the reference cell REF1 (still driven by the standard gate voltage VCCR_REF) must be programmed further (relative to FIG. 3A) in order to pass the read ‘1’ operation by VTNH.

FIG. 3C illustrates the reference cell REF1 at various program states along the process of being programmed including its native state in which it fails the read ‘1’ operation, an interim state in which the cell REF1 has been partially programmed, yet still fails the read ‘1’ operation, and a state in which the further programmed reference cell signal is smaller than the array cell's signal and so it passes the read ‘1’ test. At this last state, it is ensured that the threshold voltage of the reference cell has been raised by at least the M margin relative to VTNH.

FIG. 3D illustrates the signal development in the sense amplifier used in conjunction with the Rd_reference cell and erased and programmed cells in the array due to the normal user operation of erase and program.

It will be understood by those skilled in the art that a similar effect (but opposite in direction), can be achieved by changing the VCCR_REF by a margin M using internal/external trimming while keeping the VCCR at a fixed level.

A read operation or “sensing” of a cell may be performed as described in U.S. Pat. No. 6,535,434, which describes the steps taken to sense a close to ground signal and other sensing methods (e.g., DC current sensing).

The foregoing description parallels the method of U.S. Pat. No. 6,584,017, which goes on to describe methods for finding VTNH. Those methods may be suitable for memory devices with a relatively small number of sense amplifiers and reference cells and small number of array cells. However, as the number of sense amplifiers increases, the number of reference cells increases, and the amount of time spent on finding VTNH for all the sense amplifiers increases dramatically The increase in the array size increases the time as well.

One problem is that when performing read, the read operation never reads data related to just one ref cell. For example, in the data flash products the read is always a full page, so all of the array must be read many times for each reference cell. In other products like code flash, where there is random access, one may read a single Word/Byte but still it contains the information of a few ref cells and it will be a slower read mode than the synchronous mode. It is complicated externally to read, store and analyze all the bits for each reference cell in order to determine the pass/fail, (although some types of testers can handle it with proper configuration). Second, since the cell address with the VTNH is unknown, the entire relevant area (that can be the entire array), must be read again after each pulse to check if another program pulse must be applied. Third, each reference cell needs another set of programming pulses, because the reference cells are slightly different from one another. The difference stems from the different native Iref, the different VTNH value, and the different program speed, so the array must be read for each reference cell after each pulse to check if another program pulse must be applied The present invention may be used to solve the above problems and efficiently program the reference cells, as is now described in detail.

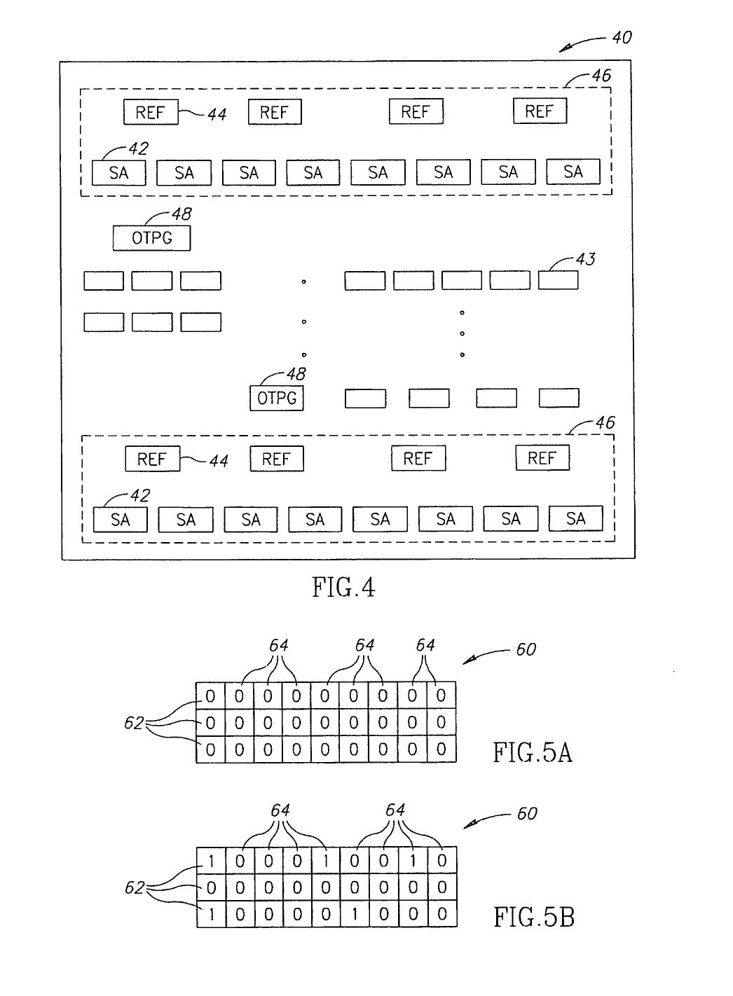

Reference is now made to FIG. 4, which illustrates a very simplified block diagram of a memory cell array 40 comprising sense amplifiers 42 and reference cells 44, for which the methods of the present invention will be described. Memory cell array 40 may comprise, without limitation, nitride, read-only memory (NROM) cells 43, which may be connected to word lines and bit lines. It is emphasized that the illustration of FIG. 4 is exemplary only, and the present invention is not limited to this example.

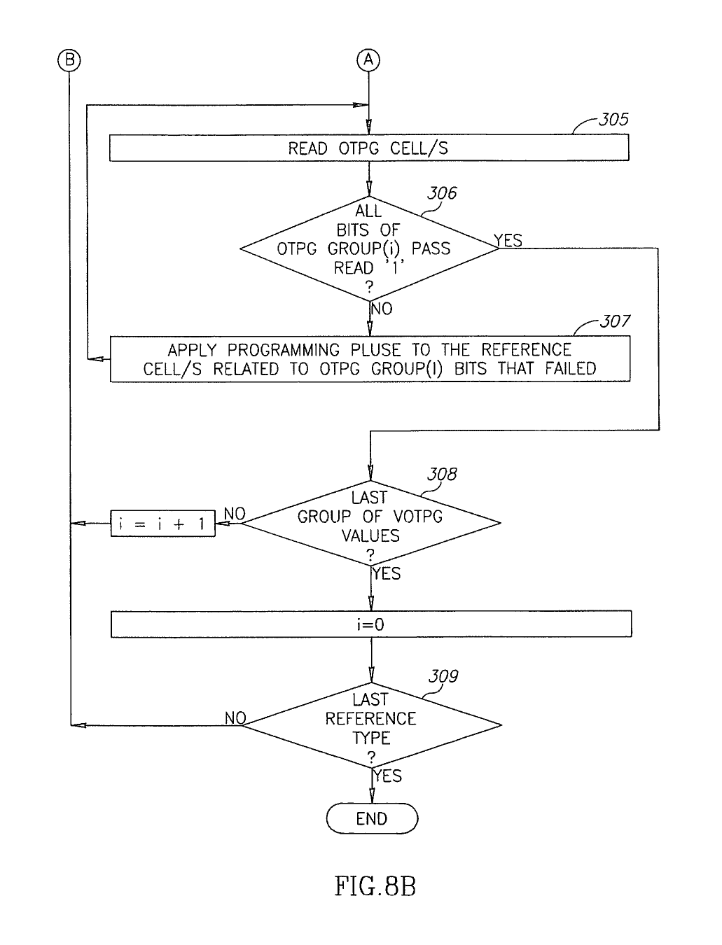

The part of the memory cell array 40, used for the reference cells, may comprise mini-arrays 46. By way of non-limiting example only, there may be a total of 256 sense amplifiers 42 for array 40. For each eight sense amplifiers 42, there may be a mini-array 46 with four reference cells 44 (but cases of one or more reference cells per SA are also covered by the present invention). The mini-array 46 may comprise a small array of bit lines and word lines. The reference cells (e.g., Read, EV, RV and PV) may be inside mini array 46. Each sense amplifier 42 may also be connected to one or more OTP (one-time-programmable) cells 48, which may be read relative to the reference cells 44 and sense amplifier 42 as described herein below with reference to FIGS. 8A and 8B. The sense amplifiers 42 and OTP cells 48 may be outside mini-array 46

The array 40 or mini-arrays 46 may have column redundancy (CR) and row redundancy (RR), wherein one or more (e.g., two) columns and rows, respectively, are dedicated for storing redundant array cells. As such, there may be two extra sense amplifiers 42 for reading the slices of the column redundancy and two extra sense amplifiers 42 for reading the slices of the row redundancy. The four reference cells 44 for each group of sense amplifiers 42 may comprise reference cells for Rd (Read), EV (Erase Verify), PV (Program Verify), and RV (an intermediate level between Read and Program Verify). (It is noted that other reference cells may also be used.) Each reference cell 44 may be programmed to a different level and may be used to read the cells, respectively during Normal Read (Rd ref), Erase (EV ref), Program (PV ref) and Program (RV ref).

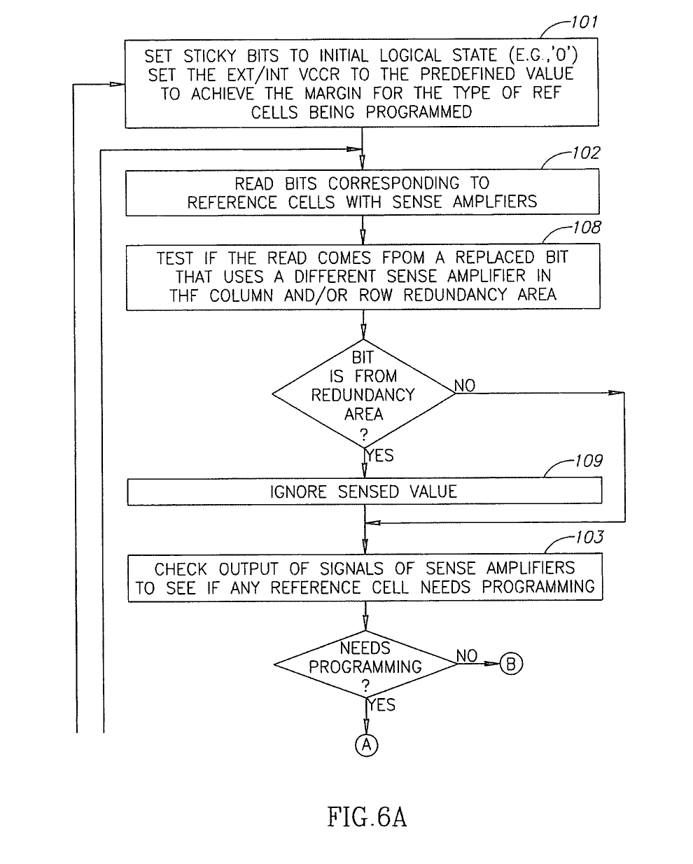

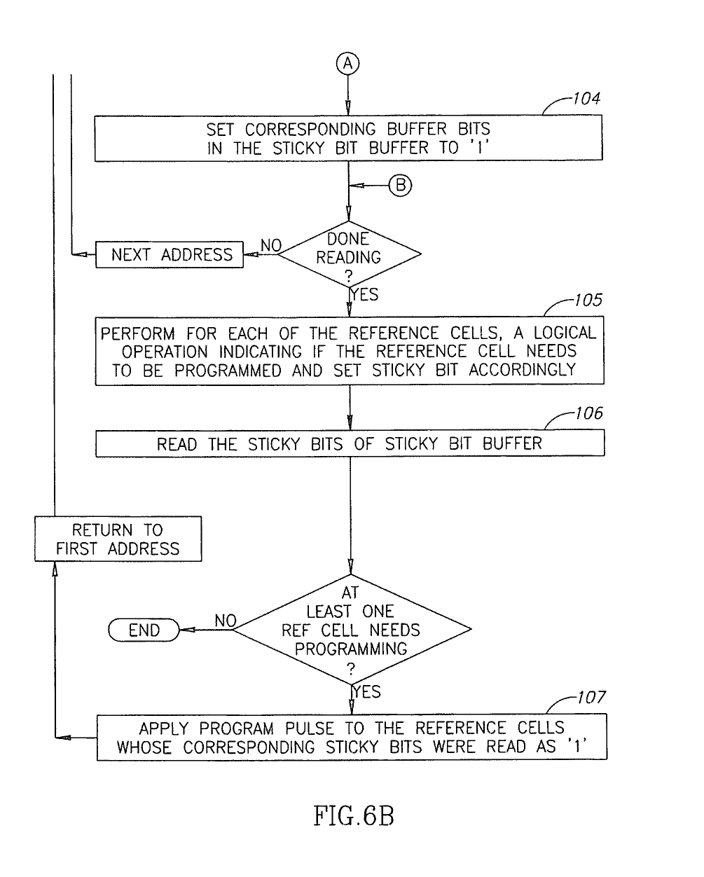

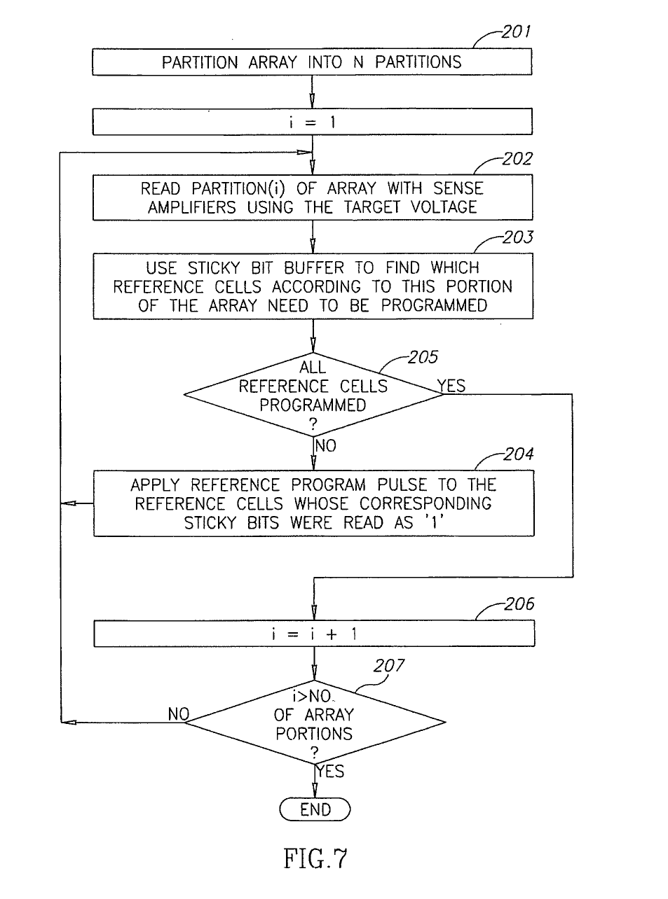

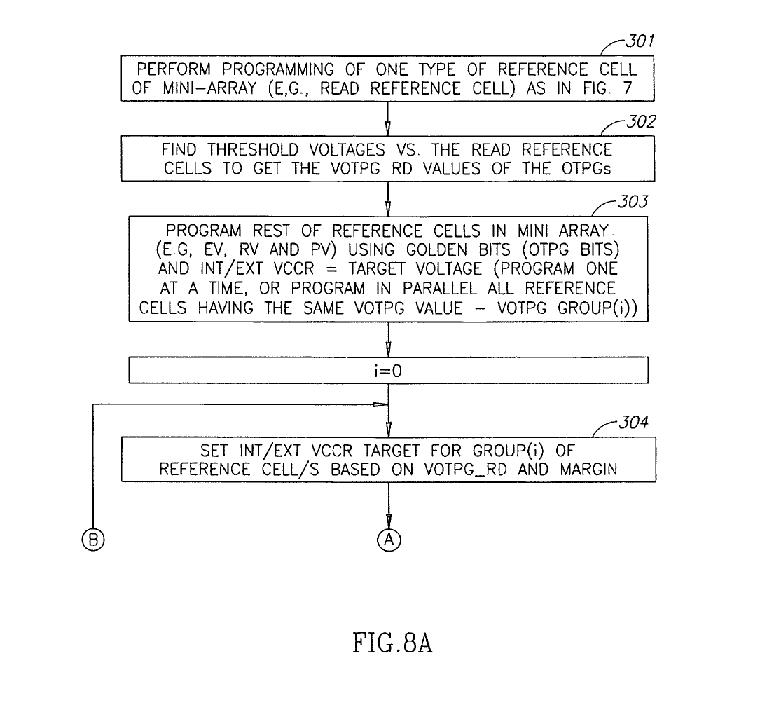

In accordance with an embodiment of the invention, and in contradistinction to U.S. Pat. No. 6,584,017, all the reference cells 44 of the same type of read operation (of mini-array 46 or array 40) may be read and programmed in parallel using a sticky bit buffer 60, as is now described pictorially with reference to FIGS. 5A-5B and in the flow chart of FIGS. 6A and 6B. (The flow chart of FIGS. 6A and 6B is an exemplary general case for programming the reference cells 44. Further advantageous methods for programming the reference cells 44 are described further hereinbelow with reference to FIGS. 7, 8A, 8B and 9.). The present invention is not limited to parallel programming of the same type of ref cell. Rather programming all the ref cells (of different types) together is also a possibility that can be done by extending the flow below. The sticky bit buffer 60 may comprise a volatile or non-volatile memory buffer. For example, sticky bit buffer 60 may comprise a random access memory, such as but not limited to, a static random access memory (SRAM) or dynamic random access memory (DRAM), which generally comprise a multiplicity of addresses for writing therein data. As an advantageous example, sticky bit buffer 60 may comprise an SRAM buffer that already exists in the system that comprises array 40.

The sticky bit buffer 60 may have one sticky bit 64 per sense amplifier 42. Initially, the sticky bits 64 may be reset to an initial logical state (e.g., ‘0’), as seen in FIG. 5A and in step 101 of the flow chart of FIGS. 6A and 6B. The external/internal VCCR may be set to a predefined value to achieve the margin for the type of reference cells being programmed. Any amount of bits or groups of bits (e.g., bytes) that may correspond to reference cells 44 may be read by the sense amplifiers 42 (step 102, FIG. 6A). Preferably, although not necessarily, a plurality (e.g., all) of the reference cells 44 of the same type may be read in parallel. The output signal of the sense amplifier 42 may be checked, while using predefined VCCR voltage (internal or external) during programming flow stages, (e.g., step 202 in FIG. 7) to see if it passes or fails the particular read operation, as described hereinabove, that is, to check if the reference cell 44 needs programming or not (step 103, FIG. 6A).

If the sense amplifier output indicates that a particular reference cell bit should be programmed, then a corresponding buffer bit 64 in the sticky bit buffer 60 is set to a first logical state (e.g., ‘1’) (step 104, FIG. 6B).

The process of updating the sticky bit buffer 60 is preferably accumulative, wherein steps 102 up to 104 are repeated as many times as necessary to read bits corresponding to reference cells 44 with the sense amplifiers 42 until completing reading the particular portion of array 40 (e.g., 1/64 of the array 40). After each reading (for example, of 256 bits by the 256 sense amplifiers 42), the sticky bit buffer 60 may be updated (i.e., step 104 is performed) only upon detection of a “need to program” bit. Accordingly, if one buffer bit 64 in the sticky bit buffer 60 has been set to the first logical state (e.g., ‘1’) at some point, then that first logical state will not be overridden if no “need to program” bit is found in further repetitions of steps 102 up to 103.

It is noted here that the present invention is not limited to the meaning of “passing” or “failing” the particular read operation. That is, the system for testing the cells could be designed such that passing the read operation means that the cell must be programmed. Alternatively, the system for testing the cells could be designed such that failing the read operation means that the cell must be programmed. The invention is thus not limited to any particular way of determining that the cell must be programmed.

The buffer bits 64 are thus set to the first or second logical state for any desired number of reference cells 44. The buffer bits 64 thus provide an indication per SA if the reference cell needs to be programmed (buffer bit set to ‘1’) or not (buffer bit set to ‘0’).

As described above, the sticky bits are preferably determined only by reading the sense amplifiers 42, not by the state of other bits in the sticky bit buffer 60. The process of reading and determining the data per reference cell 44 may be carried out externally by the tester that tests the cells, (however it requires reading externally all the data, while doing it internally may be in many cases much faster). Optionally, the sticky bit buffer 60 or another internal buffer may contain the data per reference cell 44 rather than per sense amplifier 42. Such an option may be used, for example, if there is more than one sense amplifier 42 per reference cell 44. An example of such internal implementation is illustrated in FIGS. 5A and 5B, as the leftmost column bits (marked as bits 62). Here the bits 64 to the right of this column contain the data per SA while the data per Ref may be calculated and stored in the sticky bits 62 (step 105, FIG. 6B), upon termination of a read stage.

The sticky bits 62 of sticky bit buffer 60 may then be read (step 106, FIG. 6B). A program pulse (with program data based on content of the sticky bits 62), may be applied to the reference cell or cells 44, wherein one of their corresponding sticky bits 62 was read as ‘1’ (step 107, FIG. 6B). It is clear that in a case where there is one SA per ref cell, the sticky bits 62 are redundant, and the regular sticky bits 64 can replace them.

Thus the present invention provides a method for parallel reference programming, which may be used even for large numbers of reference cells, such as in mass storage applications.

The method may optionally avoid taking into account the column and/or row redundancy area while dealing with the reference cells 44 of the main array 40. The method may test if the read (the output of the sense amplifier 42) comes from a replaced bit that uses a different sense amplifier in the column and/or row redundancy area (step 108, FIG. 6A). The determination that the bit is associated with the column and/or row redundancy area may be accomplished by any convenient method, such as but not limited to, a masking process. If so, then the sensed value is ignored (step 109) and the method continues as described hereinabove.

The foregoing description with reference to FIGS. 6A and 6B is an exemplary general case for programming the reference cells 44. Reference is now made to the flow chart of FIG. 7, which illustrates another advantageous method of the present invention for programming reference cells.

The array 40 may be partitioned into N portions (step 201). A first portion (that is, 1/N) of array 40 may be read by sense amplifiers 42 with the trimmable external/internal voltage supply (VCCR), mentioned hereinabove with reference to FIG. 2A, as a target voltage, wherein the target voltage may equal the measured VCCR_Ref-EM-CM (step 202). It is noted that in general the target voltage may be corrected due to differences in reading the array while performing the reference programming flow and the normal read operation or any other reason.

The sticky bit buffer 60 may be used to find which of the reference cells 44, which were used to read this portion of the array 40, need to be programmed (step 203), as described hereinabove with reference to FIGS. 6A and 6B. A reference program pulse may accordingly be applied to the reference cell or cells 44 whose corresponding sticky bits 62 were read as ‘1’ (step 204 in FIG. 7, corresponding to step 107 in FIG. 6B).

Steps 202-204 (i.e., reading 1/N of the array 40, checking which reference cells 44 need programming, and applying reference program pulses) may be repeated until all the reference cells 44 are considered properly programmed (step 205).

The method may then shift to the next portion (1/N or some other size portion, such as 1/M wherein N does not equal M) of the array 40 (step 206) and steps 202-204 may once again be repeated until all the sense amplifiers 42 of this portion of the array 40 sense that the reference cells are programmed to the desired level.

The method of FIG. 7 may provide several advantages:

a. Instead of reading the entire array 40 many times, only a portion (1/N) of the array 40 is read many times, thus saving time.

b. The size of the portions of the array 40 may be changed as desired.

c. After reading a few such 1/N portions, it is highly likely that almost no further program pulses may be needed, and that the rest of the 1/N portions may be read only once or twice.

d. The programming conditions of each reference cell 44 may be monitored while advancing through the array portion. Accordingly, the programming pulse being currently applied to the reference cell 44 may be selected as a function of the previous programming pulse of that specific cell. The programming pulse may be modified in any manner, such as but not limited to, modifying the voltage level, time duration or the value of the margins. In general, reading and programming part of the array may be repeated while using different programming conditions. This may reduce the number of programming pulses needed, speed up convergence and avoid over-programming

e. There is no need to initially find the highest VTNH and then afterwards program the reference cells, as in the prior art. Rather the process performs reference programming and finds the VTNH memory cell in parallel (the programming and VTNH are “intermixed”). The other types of reference cells (e.g. erase verify, refresh verify and program verify) may be programmed in the same manner as described above for the first type of reference cells or an alternative method may be used as described in the next section.

The concept of the sticky bit buffer in the present invention does not require partitioning the array. In general, there may be cases (such as described with reference to FIGS. 6A and 6B) where the array is not partitioned into N parts and the full array is read each time (such may be the case with a small array or if it desired to simplify the flow). In such cases, the above concept of the sticky bit buffer may be extended in the following way: a real sticky operation may be performed when programming the reference cells, so as to avoid applying another programming pulse to a reference cell that was once read as “pass” after reading the full array.

An example is the case wherein the initial state of the sticky bit buffer (for an example of a unit with 64 sense amplifiers) is “FFFFFFFF” after the initial reset (this is an example that has opposite initialization and a different number of sense amplifiers, which shows the generality of the process flow). In the example being considered, after performing the first read operation, all the reference cells may still need a program pulse and “00000000” may be read in the sticky bit buffer after the first read operation.

For purposes of the example, it is assumed that the program data for programming the 64 reference cells (1 per SA) is now all “0”. A second buffer may be provided that keeps the program data, being referred to as the program data buffer. Its initial value may be all “0”. This value may perform an “OR” operation with the content of the above sticky bit buffer. In this case the result of this “OR” operation is “00000000”-but in principle may also be “00000001” if reference cell #0 does not need a pulse (if it is already beyond the target).

A program pulse may then be applied to all reference cells (using the program data buffer) and a read of the array 40 is performed again, while updating the sticky bit buffer. For purposes of this example, it is supposed that the sticky bit buffer is now “00000002”-meaning that reference cell # 1 has reached it target The “OR” operation may be performed with the program data buffer to create the new program data buffer, meaning that “00000002” will be obtained as the new program data buffer. The program data buffer may then be used as the program data for the second program pulse, and a read array operation is performed again. For purposes of this example, it is supposed that “00000000” is obtained. The “OR” operation may be performed again with the program data buffer with the result again being “00000002” as the new program data buffer. This means that reference cell #1 will never again receive a program pulse even if it will be read as a reference cell that still needs to get a pulse Some non-limiting advantages of this option are simplification of the process flow faster programming of certain reference cells, and less over-programming.

Thus, in accordance with an embodiment of the present invention, wherein it is desired to read the full array, the real sticky operation may be employed This may be accomplished by employing another buffer whose initial content is all “0” or all “1” depending on the internal data for giving a program pulse to all reference cells. After completing the read array and obtaining the sticky bit buffer data, the program data buffer may be updated such that the final result is new program data buffer data=(sticky bit buffer data) OR (current program data buffer data). The content of this program data buffer may be used for programming the reference cells.

Reference is now made to FIGS. 8A and 8B, which illustrate a method for programming the reference cells 44, in accordance with yet another embodiment of the present invention.

As mentioned in U.S. Pat. No. 6,584,017, memory devices are generally tested after manufacturing to detect malfunctioning or marginal devices. As part of these tests, the array cells may be programmed. Afterwards, the device may be introduced to a relatively high temperature cycle. After this high temperature cycle, the threshold voltage of the array cells may drop by some amount. This threshold voltage drop is known as the “retention loss.” Since the reference cells are also programmed, their threshold voltage may also drop by some amount (which may be different from that of the array cells due to differences in the programming levels of the array cells and of the reference cells). Since the threshold voltages of all the programmed memory cells are affected, whether a reference cell or an array cell (including the VTNH cell), there is no relative way to determine the cell's state. A non-relative way to determine the cells' threshold voltage state, such as by an external measurement of the cells currents, is very expensive in terms of test time. Thus, an internal relative measurement of the array cells and the reference cells threshold voltages is desired.

A native cell, (or a native bit in cases with more than one bit per cell technology), which has never been programmed (or erased) and which is on-board the same die may be utilized to provide an internal relative measurement, in accordance with another aspect of the present invention. This native cell, located in an area called OTP (one-time-programming) usually used for manufacture information, is referred to herein as a “golden cell”, “golden bit” or OTPG bit 48, which will never be programmed but rather be used as a reference level. The OTPG bit 48 permits the internal read mechanism to be used for detection of array cell and reference cell threshold voltage changes after a high temperature cycle.

The OTPG bit 48 is a memory cell preferably having the same size, the same environment, similar loads and matched or similar access paths as an array memory cell. The OTPG bit 48 is usually not among the memory cells in the memory array, but rather is typically included in an auxiliary array.

One of the reference cells type of mini-array 46, such as a read reference cell, may be programmed as described hereinabove with reference to FIG. 7 (step 301, FIG. 8A). The threshold voltages of the OTPG cells may be read versus the read reference cells to get the Votpg_RD values of the OTPG cell (step 302). The rest of the reference cells in the mini array 46 (e.g., EV, RV and PV) may then be programmed using the golden bits (OTPG bits) 48 and the corresponding internal/external Vccr according to their margin (step 303). So initially, an internal/external Vccr may be set for a group[i] of reference cell/s based on the Votpg_RD values and the required margin, e.g., CM (step 304). These reference cells may be programmed one at a time, or preferably, if they share the same programming target (VCCR Voltage), due to the fact they have the same Votpg_RD values, they may be programmed together using the OTPG bits 48 (tester/unit limitations may also determine whether the cells are programmed one at a time or together). The target voltage is a shift of the external/internal Vccr, which is determined as a function of the required margin and the value of the Votpg of the reference OTPG bits 48 relative to their reference cell, e.g., Rd_Reference cell (Votpg_Rd).

For example, if the Votpg_Rd was 3.55V for some of the reference cells, then the external/internal Vccr may be appropriately set for programming the EV reference cell (e.g., 395V if CM=400 mV) based upon the OTPG bits 48. As described in U.S. Pat. No. 6,584,017, the reference cells may be programmed by placing the golden bit signal at the target place of the reference cell being programmed (step 304), reading the relevant OTPG cell/s to determine if the ref cell/s needs a program pulse or if they have reached their target (step 305), applying a programming pulse (step 307) to all (or one) reference cells having the same Votpg value, and that need a program pulse according to the former read result (step 305). These steps are repeated until a pass read ‘1’ is detected for all OTPG bit/s of same VOTPG (step 305 and 306), as described similarly hereinabove. Then the flow repeats itself for all other VOTPG groups. Thus, the flow is as described similarly above for programming the reference cell using the VTNH cell, except that in the previous discussion, the VTNH cell signal was placed at the target place of the programmed reference cell whereas now, the golden bit cell's signal is placed at the target place of the programmed reference signal.

In the general concept of programming using VOTPG, it is noted that if the Vccr_Ref used for a reference cell (e.g., the EV reference cell has Vccr_Ref_EV) is different than the Vccr_Ref_Rd used for the Rd_Reference cell, this difference will be reflected in the target voltage that is used for the calculation of the internal/external Vccr during the reference programming.

In case not all the reference cells are programmed in parallel, the method may then shift to the next ref type in mini-array 46 of array 40 (step 309) and steps 302-308 may once again be repeated.

The present invention also contemplates changes to the flow, e.g., changing the order of the loops in the flow in a way that all OTPG groups are read (using different target voltages) and then applying a program pulse to all the ref cells (step 306 and 305) in parallel.

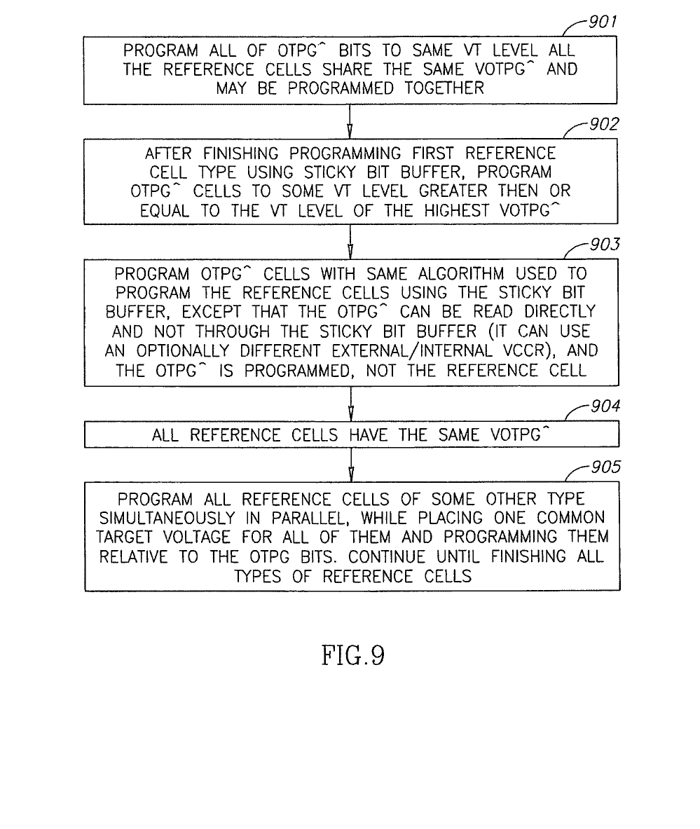

Reference is now made to FIG. 9, which illustrates a method for even faster programming of the reference cells 44, in accordance with an embodiment of the present invention. For further speeding up the programming phase that uses the OTP bits, the method may use OTPGˆ cells. These cells are different from the OTPG cells described previously, in that OTPGˆ cells will be programmed (the OTPG cells were defined as native cells that will not get program or erase pulses). For the former purpose of having a reference point after bake the method may still use other OTP bits, but for the reference programming flow, the OTPGˆs bits will be used. Now all of the OTPGˆ bits may be programmed to the same Vt level (box 901). In this way, all the reference cells share the same VOTPGˆ and may be programmed together. For example, after finishing the program phase of the first reference cell type (e.g. Rd reference cell) using the sticky bit buffer method described with reference to FIGS. 8A and 8B, all OTPGˆ cells may be programmed to some Vt level greater than or equal to the Vt level of the highest VOTPGˆ (box 902). This ensures that all OTPGˆ cells have the same Vt, achieved by programming, without having to erase some of them. The programming phase of the OTPGˆ cells may be carried out with the same algorithm used to program the reference cells using the sticky bit buffer, except that: the OTPGˆs may be read directly and not through the sticky bit buffer; the gate voltage on the OTPGˆs (external/internal Vccr) may be different than the value used in the reference cell programming; and the OTPGˆ is programmed, not the reference cell (box 903). Upon completion of this programming phase, all reference cells have the same VOTPGˆ (box 904). All the reference cells of some other type (e.g., EV) can now be programmed simultaneously in parallel, while placing one common target for all of them and programming them relative to the OTPGˆ bits (box 905). The process may continue until finishing all types of reference cells.

For generality, the programming of the OTPGˆ cells to the same Vt, may be done not relative to one of the regular ref cells but relative to a special ref cell (used only for this purpose) or by using some external/internal level of a current source.

It is noted that the methods of the invention using the sticky bit, OTPG, etc. can either be performed externally or internally by the chip.

It will be appreciated by persons skilled in the art that the present invention is not limited by what has been particularly shown and described hereinabove. Rather the scope of the present invention includes both combinations and subcombinations of the features described hereinabove as well as modifications and variations thereof which would occur to a person of skill in the art upon reading the foregoing description and which are not in the prior art.

What is claimed is:

1. A method for programming in parallel reference cells to be used for operating other cells of a memory cell array, the method comprising:
a) reading each of the reference cells of a memory cell array with a sense amplifier, the sense amplifier providing an output indicative of a programmed state of the reference cell relative to another bit in the array,
b) reading each of the reference cells of a memory cell array with a sense amplifier while using read conditions to determine if the reference cells have reached a target level,
c) determining if a programming pulse should be applied to the reference cell by comparing the output of the sense amplifier to a predefined target “0” or “1”,
d) setting a buffer bit, corresponding to the output of the sense amplifier, in a sticky bit buffer to a first logical state if the reference cell needs to be programmed, and not changing a logical state of the buffer bit if the reference cell does not need to be programmed,
e) performing steps a)-d) for a desired address range in the array,
f) performing steps a)-d) for a desired number of reference cells,
g) setting a sticky bit of the sticky bit buffer to a first logical state if one of the buffer bits indicates that one of the reference cells must be programmed, and if none of the buffer bits indicates that one of the reference cells must be programmed, then not changing a logical state of the sticky bit,
h) reading the sticky bit, and
i) applying a program pulse to the reference cell whose corresponding sticky bit is set to the first logical state.

2. The method according to claim 1, further comprising applying at least one program pulse to said reference cell until said reference cell is considered programmed relative to a predefined programmed level.

3. The method according to claim 1, further comprising reading a plurality of reference cells of said memory cell array in parallel.

4. The method according to claim 1, further comprising performing a logical operation on said buffer bits in order to determine if one of said reference cells must be programmed, said logical operation comprising a logical ‘OR’ of said buffer bits.

5. The method according to claim 1, further comprising repeating steps a)-i) until a plurality of said reference cells of said memory cell array are programmed relative to a predefined programmed level.

6. The method according to claim 1, wherein said sticky bit buffer comprises a random access memory.

7. The method according to claim 1, wherein said sticky bit buffer comprises one sticky bit per sense amplifier.

8. The method according to claim 1, wherein said sticky bit buffer comprises one sticky bit per more than one sense amplifier.

9. The method according to claim 1, wherein said reference cells comprise at least one of a reference cell for read, erase verify, program verify, PBEV (Program Before Erase Verify), PAEV (Program After Erase Verify), and an intermediate level between read and program verify.

10. The method according to claim 1, wherein the output of said sense amplifier corresponds to a redundancy area of said memory cell array.

11. The method according to claim 1, wherein steps a)-i) are performed on a portion of said memory cell array defined as 1/N of said memory cell array.

12. The method according to claim 11, wherein after performing steps a)-i) on the 1/N portion of said memory cell array, steps a)-i) are performed oil another portion of said memory cell array defined as 1/M of said memory cell array, wherein N does not equal M.

13. The method according to claim 11, wherein after performing steps a)-i) on the 1N portion of said memory cell array, further comprising performing steps a)-i) on another portion of said memory cell array defined as 1/M of said memory cell array with different programming conditions.

14. The method according to claim 13, wherein N does not equal M.

15. The method according to claim 1, wherein applying the program pulse to the reference cell comprises using an OTPG (one-time-programmable golden) reference bit on said memory cell area, wherein said OTPG bit is not programmed or erased during application of the method.

16. The method according to claim 15, further comprising using a predefined voltage level in the reading of said OTPG bit to program another reference cell of said memory cell array.

17. The method according to claim 15, wherein said array comprises a plurality of OTPGˆ bits, and the method further comprises programming all the OTPGˆ bits to the same Vt level.

18. The method according to claim 1, further comprising employing a real sticky operation to read then entire memory cell array, obtaining sticky bit buffer data, and updating another buffer called a program data buffer wherein the new program data buffer data=(sticky bit buffer data) OR (current program data buffer data), and wherein the content of said program data buffer is used to program the reference cells.
